(19) United States
(12) Patent Application Publication
(10) Pub. No.: US 2009/0061637 A1
(43) Pub. Date: Mar. 5, 2009

(54) MANUFACTURING METHOD FOR SEMICONDUCTOR DEVICE

(76) Inventor: Hiroshi IWATA, Onomichi-shi (JP)

Correspondence Address: NIXON & VANDERHYE, PC, 901 NORTH GLEBE ROAD, 11TH FLOOR, ARLINGTON, VA, 22203, US

(21) Appl. No.: 12/197,547

(22) Filed: Aug. 25, 2008

(30) Foreign Application Priority Data
Aug. 31, 2007 (JP) 2007-226049

(51) Int. Cl. H01L 21/311

(52) U.S. Cl. 438/703; 257/E21.249

(57) ABSTRACT

A manufacturing method for a semiconductor device includes: forming a first material film, a second material film, each having a function of preventing metal diffusion, and a third material film of which the etching rate for a first etchant is sufficiently lower than that of the first material film and the etching rate for a second etchant is sufficiently lower than that of the second material film, in this order on the outer peripheral surface of the semiconductor substrate; forming a trench structure; forming a buried insulating film and flattening it; removing the second material film through a wet etching process using the second etchant until the first material film formed on the main surface side is exposed; and removing the first material film on the main surface side through a wet etching process using the first etchant until the semiconductor substrate is exposed on the main surface side.

### CROSS REFERENCE TO RELATED APPLICATION

This Nonprovisional application claims priority under 35 U.S.C. §119(a) on Patent Application No. 2007-226049 filed in Japan on Aug. 31, 2007, the entire contents of which are hereby incorporated by reference.

### BACKGROUND OF THE INVENTION

1. Field of the Invention

The present invention relates to a manufacturing method for a semiconductor device, and in particular, to a manufacturing method for a semiconductor device having a structure for preventing heavy metal pollution from the rear surface of a semiconductor substrate.

2. Description of the Related Art

Semiconductor devices, such as CPU's (central processing units), which are semiconductor integrated circuits, memory elements and solid state imaging devices, are manufactured by forming various types of circuit elements (semiconductor devices) on the main surface of a semiconductor substrate made of single crystal silicon, for example. In the manufacture of conventional semiconductor devices, the quality and properties of the manufactured semiconductor devices significantly deteriorate when an impurity of a metal, particularly a heavy metal, is mixed in the inside of the semiconductor substrate. In solid state imaging devices, for example, the presence of heavy metal contaminants in the semiconductor substrate causes and/or induces defects, and thus is a factor in the deterioration of the transistor properties and properties in the dark of the solid state imaging device.

In recent years, Cu (copper) particularly has tended to be used as materials for wires instead of the conventional Al (aluminum), in order to reduce the wire resistance. Since Cu has a low resistivity in comparison with Al, the wire resistance can be reduced by using Cu as the material for the wires. However, since Cu has a high diffusion coefficient, there is a fear that Cu may diffuse into the semiconductor substrate and cause the properties to deteriorate, as described above. Accordingly, particularly in the case where a semiconductor device is manufactured using a metal material having a high diffusion coefficient, it is necessary to take measures to prevent the metal material from diffusing into the semiconductor substrate. As an example of conventional manufacturing methods for semiconductor devices in which such measures are taken, there are methods disclosed in Japanese Unexamined Patent Publication No. 2000-91175 (hereinafter referred to as Publicly Known Document 1) and Japanese Unexamined Patent Publication No. 2001-44168 (hereinafter referred to as Publicly Known Document 2). In the following, these methods are described in reference to the figures.

FIGS. 3A to 3E are schematic cross sectional views illustrating the manufacturing method for a semiconductor device described in Publicly Known Document 1 in the order of manufacturing steps.

As shown in FIG. 3A, first, a silicon oxide film 102 is formed over the entire surface of a semiconductor substrate 101, in which an element isolation region having an STI (shallow trench isolation) structure and a chip region are formed on the main surface side, through thermal oxidation or the like. Next, a silicon nitride film 103 is deposited on the silicon oxide film 102 in accordance with, for example, an LPCVD (low pressure chemical vapor deposition) method. Then, a polysilicon film 104 is deposited on the silicon nitride film 103 in accordance with an LPCVD method or the like, and furthermore, a silicon nitride film 105 is deposited on the polysilicon film 104 in accordance with an LPCVD method or the like.

Next, as shown in FIG. 3B, a photoresist 106 is applied to the silicon nitride film 105 on the main surface of the semiconductor substrate 101, and this is patterned so that the photoresist 106 is removed in the periphery portion of the semiconductor substrate 101. Then, using this patterned photoresist 106 as a mask, the silicon nitride film 105 which is exposed in the peripheral portion on the main surface, and on the outer peripheral surface and the rear surface is removed through anisotropic etching such as an RIE (reactive ion etching) method. That is, the region for forming a chip on the main surface, excluding the periphery portion, is coated with the silicon nitride film 105 and the photoresist 106 on top thereof (see FIG. 3B).

Next, as shown in FIG. 3C, after removal of the photoresist 106, the polysilicon film 104 is oxidized in the peripheral portion on the main surface and on the outer periphery surface and the rear surface of the semiconductor substrate 101 through a heat treatment step, so that a silicon oxide film 107 is formed.

Next, as shown in FIG. 3D, after removal of the silicon nitride film 105, the polysilicon film 104 in the layer beneath the silicon nitride film 105 that is coated with the silicon nitride film 105 is removed in accordance with a dry etching method or the like so that the silicon nitride film 103 is partially exposed.

Next, as shown in FIG. 3E, the silicon oxide film 107 with which the peripheral portion on the main surface and on the outer peripheral surface and the rear surface of the semiconductor substrate 101 are coated is used as a mask and the exposed silicon nitride film 103 is removed using phosphoric acid or the like.

After these steps, the silicon nitride film 103 and the silicon oxide film 107 remain in the peripheral portion on the main surface, excluding the chip region on the main surface side, and on the outer peripheral surface and the rear surface. The silicon nitride film 103 and the silicon oxide film 107 can prevent metals, such as Cu, from diffusing into the semiconductor substrate 101. That is, these films 103 and 107 function as a protective insulating film for preventing metal contamination.

In addition, FIGS. 4A to 4G are schematic cross sectional views illustrating the manufacturing method for a semiconductor device described in Publicly Known Document 2 in the order of manufacturing steps.

First, a silicon oxide film 202 with a thickness of approximately 10 to 20 nm is formed on a semiconductor substrate 201, as shown in FIG. 4A, and furthermore, a silicon nitride film 203 with a thickness of approximately 300 nm is formed on top thereof. At this time, as shown in FIG. 4B, the silicon oxide film 202 and the silicon nitride film 203 are formed on the rear surface in addition to the main surface of the semiconductor substrate 201 (for the sake of convenience, the upper side of the semiconductor substrate 201 in the figures is referred to as main surface side and the lower side is referred to as rear surface side).

Next, as shown in FIG. 4C, a photoresist 204 is formed on the silicon nitride film 203 on the main surface side of the semiconductor substrate 201 and patterned.

Next, as shown in FIG. 4D, the silicon nitride film 203, the silicon oxide film 202 and the semiconductor substrate 201 are etched on the main surface side in accordance with a dry etching method, such as RIE, using the photoresist 204 as a mask and the photoresist 204 is peeled off so that a trench pattern is formed. After that, a silicon oxide film 205 is deposited on the entire surface so that the trenches in the pattern are filled with the silicon oxide film 205.

Next, as shown in FIG. 4E, the silicon oxide film 205 and the silicon nitride film 203 are etched and polished using a CMP (chemical mechanical polishing) technology until the silicon nitride film 203 becomes a predetermined film thickness after being exposed, so that the surface is flattened.

Next, as shown in FIG. 4F, the silicon nitride film 203 is selectively etched and removed. At this time, the structure shown in FIG. 4E is immersed in a phosphoric acid solution of high temperature for a predetermined period of time, in order to selectively remove only the silicon nitride film 203, without removing the silicon oxide film 205. In addition, the silicon nitride film 203 on the rear surface side is also etched and removed, in addition to the silicon nitride film 203 on the main surface side. However, the film thickness of the silicon nitride film 203 is approximately three times greater on the rear surface side than on the main surface side, and therefore, the silicon nitride film 203 on the rear surface is not entirely etched and removed, and approximately 100 nm remains, even after the above-described etching using the phosphoric acid solution for the predetermined period of time.

Finally, as shown in FIG. 4G, the silicon oxide film 202 on the surface is etched and removed using a low-concentration aqueous HF solution or the like, so that an STI structure is formed on the semiconductor substrate 201. At this time, the rear surface of the semiconductor substrate 201 is coated with a silicon oxide film 202 and a silicon nitride film 203.

Also in the case where the method described in Publicly Known Document 2 is used, the silicon oxide film 202 and the silicon nitride film 203 can be left on the rear surface side of the semiconductor substrate 201. As a result, metals, such as Cu, can be prevented from diffusing into the semiconductor substrate 201.

In accordance with the methods in Publicly Known Documents 1 and 2, metals can be prevented from diffusing into the semiconductor substrate.

In the case of the method described in Publicly Known Document 1, however, a photolithographic step, in which the polysilicon film 104, the silicon nitride film 105 and the photoresist 106 are applied, and a subsequent step for oxidizing the polysilicon film 104 are necessary in order to coat the peripheral portion on the main surface and on the outer peripheral surface and the rear surface of the semiconductor substrate, with the silicon nitride film 103 and the silicon oxide film 107, and thus a problem arises in which a great number of steps are required in addition to those in usual methods for forming an STI structure. In particular, in the method described in Publicly Known Document 1, it is necessary to form the polysilicon film 104 and the silicon nitride film 105 after an STI structure has been formed in advance. The steps for forming these films 104 and 105 are not required when the STI structure is formed, but are required only when a protective insulating film is formed, and therefore, may become a factor in the high cost of manufacture.

In addition, in the case of the method described in Publicly Known Document 2, the surface of the silicon oxide film 205 formed on the main surface side is flattened, and after that, as shown in FIG. 4F, it is necessary that the silicon nitride film 203 on the main surface side is completely etched and removed, while the silicon nitride film 203 on the rear surface side is not completely removed and remains at a predetermined film thickness. Therefore, there is a problem that it is required to control the film thickness to a considerably high degree in order to keep good balance in the film thickness of the silicon nitride film 203 between the main surface side and the rear surface side of the semiconductor substrate 201. In particular, the film thickness of the silicon nitride film 203 on the main surface side is easily affected by the density of the pattern on the surface at the time of CMP polishing, and thus, the lower limit for the immersion time in phosphoric acid is determined on the basis of the pattern in which the amount of a film that remains is locally great. That is, the amount of the silicon nitride film 203 that remains on the rear surface side is uniquely determined by the amount of etching during the above-described lower limit time. Accordingly, it becomes difficult to control etching so that a film thickness required in order to gain the effects of preventing metal contaminants from diffusing into the semiconductor substrate remains.

### SUMMARY OF THE INVENTION

In view of the above-described problems, an object of the present invention is to provide a simple manufacturing method for a semiconductor device in which increase in the number of steps is restricted to the minimum and which can prevent metals from diffusing into a semiconductor substrate.

In order to achieve the above-described object, the manufacturing method for a semiconductor device according to a first aspect of the present invention comprises: a first step of forming a first material film having a function of preventing metal diffusion, a second material film having the function of preventing metal diffusion, made of a different material from that of the first material film, and a third material film of which the etching rate for a first etchant is sufficiently lower than that of the first material film and the etching rate for a second etchant is sufficiently lower than that of the second material film, in this order on at least the main surface side and the rear surface side of a semiconductor substrate; a second step of patterning the multilayer structure of the first material film, the second material film and the third material film into a predetermined form on the main surface side of the semiconductor substrate so that the semiconductor substrate surface is partially exposed from the main surface side after the completion of the first step; a third step of etching and removing the third material film which remains on the main surface side after the completion of the second step, and carrying out a dry etching process on the semiconductor substrate exposed on the main surface side so that a trench structure is formed; a fourth step of forming a buried insulating film from a different material from the second material film on the entire surface of the main surface side after the completion of the third step; a fifth step of carrying out a flattening process on the main surface side until the surface of the second material film is exposed on the main surface side after the completion of the fourth step; a sixth step of carrying out a wet etching process using the second etchant so that the second material film on the main surface side is etched and removed until the first material film formed on the main surface side is exposed after the completion of the fifth step; and a seventh step of carrying out a wet etching process using the first etchant so that the first material film on the main surface side is etched and removed until the semiconductor substrate surface is exposed on the main surface side after the completion of the sixth step, wherein the first step includes forming the third material film having a thickness that is greater than the thickness by which the third material film is etched in the sixth and seventh steps.

In the manufacturing method for a semiconductor device according to the above-described first aspect of the present invention, the first, second and third material films are formed on the rear surface side in addition to the main surface side in the first step. Then, the main surface side is patterned in the second step, and after that, a trench structure is formed on the semiconductor substrate in the third step. Even at this time, a state where the first to third material films are formed is maintained in regions other than the main surface side of the semiconductor substrate, for example on the rear surface side. On the other hand, the third material film on the main surface side is removed in the third step, and therefore, the state becomes such that first and second material films are formed in regions where the trench structure is not formed.

After that, a buried insulating film is formed over the entire surface, including the surface inside of the trench structure, in the fourth step, and then, a flattening process is carried out in the fifth step. Even at this point in time, a state where the first to third material films are formed in regions other than the main surface side of the semiconductor substrate, for example on the rear surface side, is maintained. In addition, the second material film on the main surface side is etched and removed in the sixth step, and the first material film on the main surface side is etched and removed in the seventh step, in both cases through a wet etching process.

Here, as described above, the first to third material films are formed in regions other than on the main surface side after carrying out the fifth step. From among these films, the third material film is on the outermost side, and the second material film and the first material film are formed in this order toward the inside, that is, toward the semiconductor substrate side. On the other hand, a buried insulating film is formed in the trench structure portion on the main surface side, and the second material film and the first material film are formed in portions other than the trench structure in this order from the outside inward (semiconductor substrate side). When the second material film on the main surface side is etched and removed by carrying out a wet etching process using the second etchant in this state, the third material film, of which the etching rate for the second etchant is lower than that of the second material film, is formed on the outermost side in regions other than the main surface side, and therefore, the etching process in the sixth step can be carried out without having to worry about the decrease of the thickness of the second material film formed inside the third material film.

As a result, even after the completion of the sixth step, a state where the third material film remains in regions other than the main surface side is maintained. When the first material film on the main surfaces side is etched and removed in this state by carrying out a wet etching process using the first etchant in the seventh step, the third material film, of which the etching rate for the first etchant is lower than that of the first material film, still remains on the outermost side in regions other than the main surface side, and therefore, the etching process in the seventh step can be carried out without having to worry about the decrease of the thickness of the first material film formed inside the third material film.

That is, in the manufacturing method for a semiconductor device according to the above-described first aspect of the present invention, it is not necessary to add a separate photolithographic step and the like in order to form only a material film for preventing metal diffusion, and thus, a material film for preventing metal diffusion can be formed on the sides and rear surface side of a semiconductor substrate through the same steps as those used to form conventional STI structures.

In addition, the film material on the outermost side of the main surface side, which is desired to be etched and removed (second material film in case of sixth step, first material film in case of seventh step), and the film material on the sides and the outermost side on the rear surface (third material film) are different materials in the wet etching process in the sixth and seventh steps. Therefore, only the film material on the main surface side which is desired to be etched and removed can be selectively etched and removed, using the difference in the etching rate between the film materials, without controlling etching by strictly observing the amount of reduction in the film material on the sides and the rear surface side, which is desired to remain. That is, it is not necessary to take the amount of reduction in the first and second material films formed on the inside of the third material film on the sides and the rear surface side into consideration. Accordingly, it becomes unnecessary to finely control etching in order to leave the film thickness required for the function of preventing diffusion on the rear surface side, unlike in the method described in Publicly Known Document 2.

Further, in the manufacturing method for semiconductor devices according to a second aspect of the present invention, the first material film is a silicon oxide film, the second material film is a silicon nitride film, and the third material film is a polysilicon film in addition to the first aspect.

In addition, in the manufacturing method for semiconductor devices according to a third aspect of the present invention, the first step includes forming the first material film in accordance with a thermal oxidation method, and forming the second material film and the third material film in accordance with a reduced pressure CVD method in addition to the second aspect.

In the manufacturing method for semiconductor devices according to the third aspect of the present invention, the first to third material films can be formed on the sides and the rear surface side of the semiconductor substrate in addition to the main surface side.

In addition, in the manufacturing method for semiconductor devices according to a fourth aspect of the present invention, the first etchant is a low concentration HF solution and the second etchant is a phosphoric acid solution in addition to the second or third aspect.

In the configuration of the present invention, a semiconductor device having effects of preventing metal diffusion into the semiconductor substrate can be manufactured in accordance with a simple manufacturing method while an increase in the number of steps is limited to the minimum. Accordingly, metal diffusion into the semiconductor substrate can be easily prevented, even in the case where a metal material having a high diffusion coefficient, such as Cu, is used as the material for the wires.

### BRIEF DESCRIPTION OF THE DRAWINGS

FIGS. 1A to 1I are schematic cross sectional views illustrating the manufacturing method for a semiconductor device according to the present invention in the same order as the manufacturing steps;

FIG. 2 is a flow chart showing the steps in the manufacturing method for a semiconductor device according to the present invention;

FIGS. 3A to 3E are schematic cross sectional views illustrating the manufacturing method for a semiconductor device according to the prior art in the same order as the manufacturing steps; and

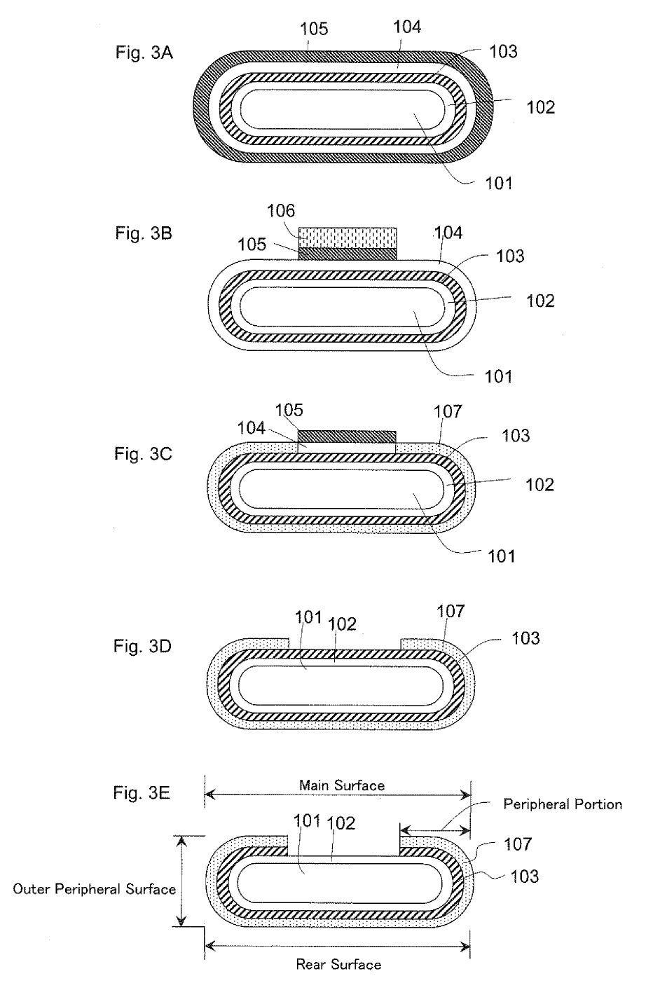

FIGS. 4A to 4G are schematic cross sectional views illustrating the manufacturing method for a semiconductor device according to another prior art in the same order as the manufacturing steps.

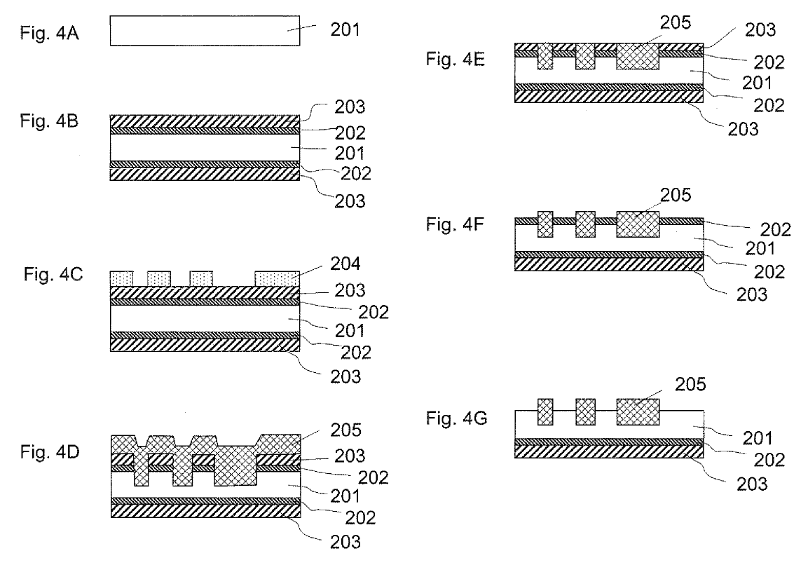

### DETAILED DESCRIPTION OF THE INVENTION

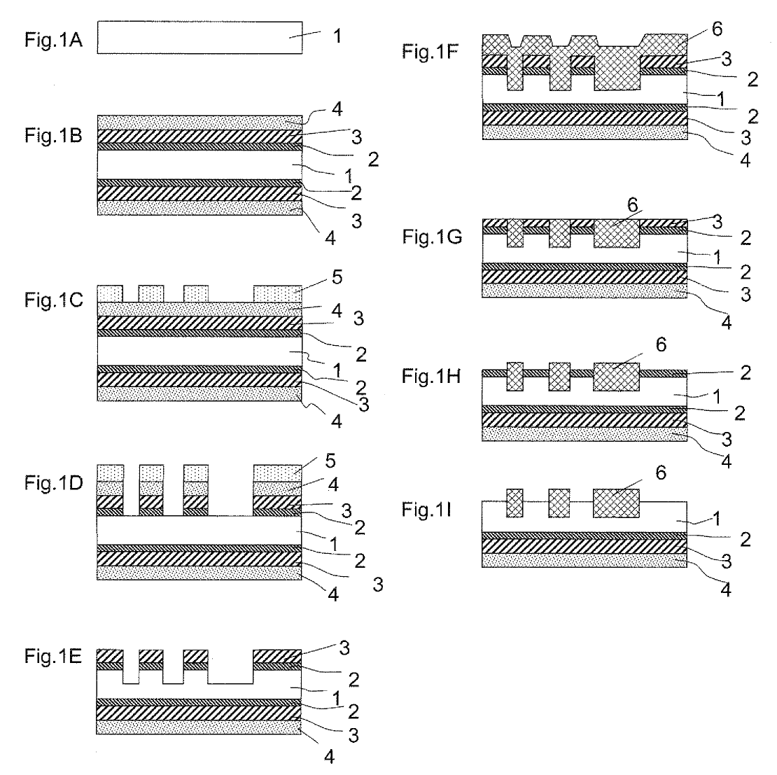

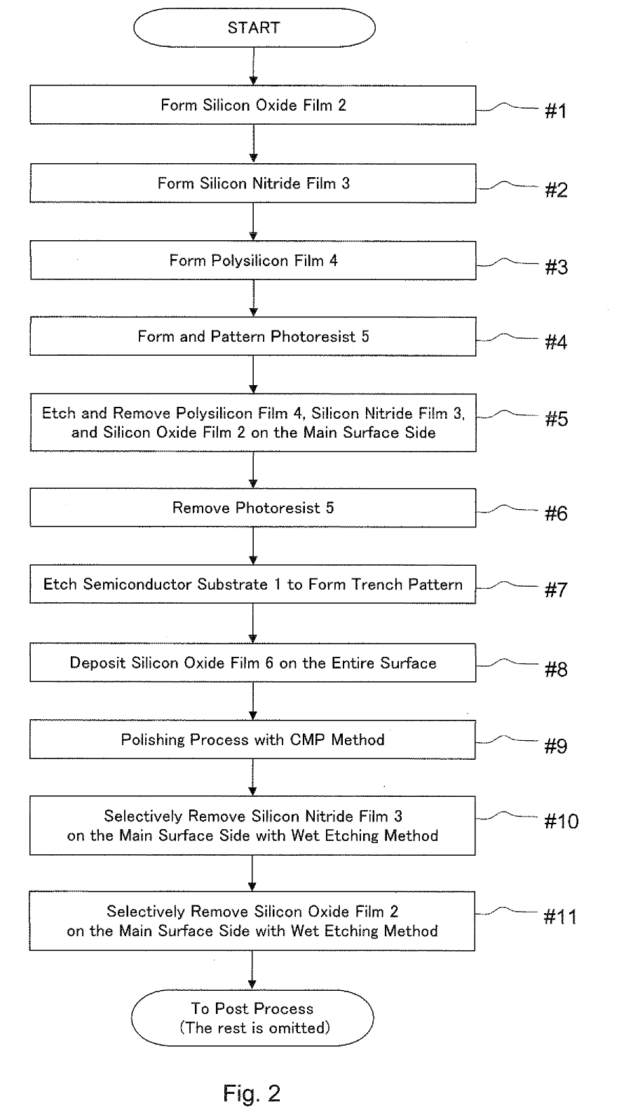

In the following, the manufacturing method for a semiconductor device according to an embodiment of the present invention (hereinafter referred to as “method according to the present invention”) is described in reference to FIGS. 1 and 2.

FIGS. 1A to 1I are schematic cross sectional views illustrating the structure in each step when a semiconductor device is manufactured using the method according to the present invention. Each of FIG. 1A to 1I shows each steps. In addition, FIG. 2 is a flow chart illustrating the manufacturing steps using the method according to the present invention, and each step in the following description represents one step in the flow chart shown in FIG. 2.

Here, FIGS. 1A to 1I are schematic cross sectional views showing the structure, and the scale in the drawings does not necessarily correspond to the actual scale.

First, as shown in FIG. 1A, a silicon oxide film 2 is formed on a semiconductor substrate 1 in a thickness of approximately 10 to 20 nm through thermal oxidation at 800° C. to 1000° C. (Step #1), a silicon nitride film 3 is formed on top thereof in a thickness of approximately 100 to 250 nm in accordance with an LPCVD (low pressure chemical vapor deposition) method (Step #2), and furthermore, a polysilicon film 4 is formed on top thereof in a thickness of approximately 50 to 100 nm in accordance with an LPCVD method (Step #3). After undergoing Steps #1 to #3, the semiconductor substrate has the silicon oxide film 2, the silicon nitride film 3 and the polysilicon film 4 on the sides and the rear surface side, in addition to on the main surface side, as shown in FIG. 1B. In the following, the upper side of the semiconductor substrate 1 on the paper is referred to as the main surface side, and the lower side is referred to as the rear surface side in FIGS. 1A to 1I for the sake of convenience.

Next, as shown in FIG. 1C, a photoresist 5 is formed on the polysilicon film 4 formed on the main surface side, and a desired pattern is formed (Step #4). Here, between Step #3 and Step #4, a reflection preventing film for a light exposure photographic process formed of an inorganic material or an organic material may be formed on the polysilicon film 4, and after that, a photoresist 5 may be formed, and thus a patterning process is carried out.

Next, as shown in FIG. 1D, the polysilicon film 4, the silicon nitride film 3 and the silicon oxide film 2 on the main surface side are respectively etched and removed in accordance with a dry etching method, such as RIE (reactive ion etching) using the photoresist 5 as a mask (Step #5).

Next, as shown in FIG. 1E, the entire surface is dry etched after the removal of the photoresist 5 (Step #6). Here, in reality, the semiconductor substrate 1 and the polysilicon film 4 on the silicon nitride film 3 are etched simultaneously, and after the polysilicon film 4 is completely removed, the silicon nitride film 3 formed in the layer beneath the polysilicon film 4 and the silicon oxide film 2 in the layer beneath the silicon nitride film function as a mask. Then, the semiconductor substrate 1 is etched through dry etching using the silicon nitride film 3 and the silicon oxide film 2 as a mask, and thus, a trench pattern is formed (Step #7).

Next, as shown in FIG. 1F, a silicon oxide film 6 is deposited on the entire surface on the main surface side in accordance with, for example, a high density plasma CVD method, so that the trench in the pattern is filled with the silicon oxide film 6 (Step #8). In Step #8, the silicon oxide film 6 is deposited in accordance with a high density plasma CVD method, and thus, the silicon oxide film 6 can be deposited only on the main surface side, and not on the rear surface side of the semiconductor substrate 1.

Next, as shown in FIG. 1G, a polishing process is carried out on the silicon oxide film 6 and the silicon nitride film 3 in accordance with a CMP Chemical mechanical polishing) method, so that the surface is flattened (Step #9).

Next, as shown in FIG. 1H, the silicon nitride film 3 on the main surface side is removed in accordance with a wet etching method, in which the structure resulting from Step #9 is immersed in a phosphoric acid solution (Step #10). As shown in FIG. 1G, the polysilicon film 4 remains on the sides and the rear surface side after Step #9 is completed. The etching rate of the polysilicon film 4 and the silicon oxide film 6 for a phosphoric acid solution is sufficiently slow in comparison with that of the silicon nitride film 3, and therefore, only the silicon nitride film 3 on the main surface side, in which the polysilicon film 4 is not formed, is selectively etched in Step #10.

Next, as shown in FIG. 1I, the silicon oxide film 2 on the main surface side is removed in accordance with a wet etching method, in which the structure resulting from Step #10 is immersed in a low concentration aqueous HF solution, and thus, an STI (shallow trench isolation) structure is formed (Step #11). The etching rate of the polysilicon film 4 for the low concentration aqueous HF solution is sufficiently slow in comparison with that of the silicon oxide film 2, and therefore, etching of the polysilicon film 4 on the sides and the rear surface side does not progress in Step #11, and only the silicon oxide film 2 on the main surface side is selectively etched and removed. As a result, the deposited films, that is, the silicon oxide film 2, the silicon nitride film 3 and the polysilicon film 4, remain on the sides and the rear surface side of the semiconductor substrate 1 even after STI is formed.

After the completion of Step #11, the silicon nitride film 3 and the polysilicon film 4, of which the film thickness is approximately the same when the films are formed in steps #2 and #3, remain on the sides and the rear surface side of the semiconductor substrate 1, and thus, a process margin can be secured.

In the method according to the present invention, when the above-described Steps #1 to #11 are carried out, an insulating film for preventing metal diffusion can be formed on the sides and the rear surface side of the semiconductor substrate 1 without adding any separate step other than that of forming an STI structure, unlike in the method described in Publicly Known Document 1. In addition, in the method according to the present invention, the film formed on the outermost side on the main surface side which is desired to be etched and removed in a wet etching process of Steps #10 and #11 and the film formed on the outermost side on the sides and the rear surface side are made of different materials. Therefore, only the film on the main surface side which is desired to be removed can be selectively etched using the difference in the etching rate between the materials of these films, without requiring etching control or paying attention to the amount of film etched off on the sides and the rear surface side, which is desired to be left. That is, such meticulous etching control as in the method described in Publicly Known Document 2 for making a film which is thick enough to have a function of preventing diffusion remain on the rear surface becomes unnecessary.

Here, though, in the above description, the silicon oxide film 2 is formed in Step #1, the silicon nitride film 3 is formed in Step #2 and the polysilicon film 4 is formed in Step #3 according the embodiment, the materials are not limited as long as, when the film formed in Step #1 is referred to as “first material film 2,” the film formed in Step #2 is referred to as “second material film 3” and the film formed in Step #3 is referred to as “third material film 4,” these materials are any material in which the etching rate of the third material film 4 for the etchant used in the wet etching process in Step #10 is sufficiently lower than that of the second material film 3, the etching rate of the third material film 4 for the etchant used in the wet etching process in Step #11 is sufficiently lower than that of the first material film 2, and the first material film 2 and the second material film 3 are both materials having a function of preventing metal diffusion. Here, in the case where a polysilicon film is formed as the third material film 4, the polysilicon film 4 on the main surface side can be simultaneously etched and removed in the dry etching process for the semiconductor substrate 1 in Step #7, and therefore, reduction in the number of steps can be achieved, which is preferable.

In addition, though a silicon oxide film 6 is formed in Step #8 in the above-described embodiment, the film is not limited to a silicon oxide film, as long as it is made of an insulating film material which is appropriate for filling in the trench, and made of a material different from the third material film 3 formed in Step #2.

In addition, though the above-described embodiment provides a configuration where the silicon oxide film 2, the silicon nitride film 3 and the polysilicon film 4 are formed on the rear surface side and the sides, in addition to on the main surface side, of the semiconductor substrate 1 in Steps #1 to #3, sufficient effects can be gained according to the present invention, even in the case where the films are formed only on the main surface side and on the rear surface side. That is, the films 2 to 4 may be formed at least on the main surface side and on the rear surface side of the semiconductor substrate 1 in the configuration.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A manufacturing method for a semiconductor device comprising:
a first step of forming a first material film having a function of preventing metal diffusion, a second material film having a function of preventing metal diffusion, made of a different material from that of the first material film, and a third material film of which an etching rate for a first etchant is lower than that of the first material film and an etching rate for a second etchant is lower than that of the second material film, in this order on at least a main surface side and a rear surface side of a semiconductor substrate;
a second step of patterning a multilayer structure of the first material film, the second material film and the third material film into a predetermined form on the main surface side of the semiconductor substrate so that the semiconductor substrate surface is partially exposed from the main surface side after completion of the first step;
a third step of etching and removing the third material film which remains on the main surface side after completion of the second step, and carrying out a dry etching process on the semiconductor substrate exposed on the main surface side so that a trench structure is formed;
a fourth step of forming a buried insulating film from a different material from the second material film on an entire surface of the main surface side after completion of the third step;
a fifth step of carrying out a flattening process on the main surface side until a surface of the second material film is exposed on the main surface side after completion of the fourth step;
a sixth step of carrying out a wet etching process using the second etchant so that the second material film on the main surface side is etched and removed until the first material film formed on the main surface side is exposed after completion of the fifth step; and
a seventh step of carrying out a wet etching process using the first etchant so that the first material film on the main surface side is etched and removed until the semiconductor substrate surface is exposed on the main surface side after completion of the sixth step, wherein
the first step includes forming the third material film having a thickness that is greater than a thickness by which the third material film is etched in the sixth and seventh steps.

2. The manufacturing method according to claim 1, wherein
the first material film is a silicon oxide film, the second material film is a silicon nitride film, and the third material film is a polysilicon film.

3. The manufacturing method according to claim 2, wherein
the first step includes forming the first material film in accordance with a thermal oxidation method, and forming the second material film and the third material film in accordance with a reduced pressure CVD method.

4. The manufacturing method according to claim 2, wherein
the first etchant is a low concentration HF solution and the second etchant is a phosphoric acid solution.

5. A semiconductor device manufactured in accordance with a process, the process comprising:
a first step of forming a first material film having a function of preventing metal diffusion, a second material film having a function of preventing metal diffusion, made of a different material from that of the first material film, and a third material film of which an etching rate for a first etchant is lower than that of the first material film and an etching rate for a second etchant is lower than that of the second material film, in this order on at least a main surface side and a rear surface side of a semiconductor substrate;
a second step of patterning a multilayer structure of the first material film, the second material film and the third material film into a predetermined form on the main surface side of the semiconductor substrate so that the semiconductor substrate surface is partially exposed from the main surface side after completion of the first step;
a third step of etching and removing the third material film which remains on the main surface side after completion of the second step, and carrying out a dry etching process on the semiconductor substrate exposed on the main surface side so that a trench structure is formed;
a fourth step of forming a buried insulating film from a different material from the second material film on an entire surface of the main surface side after completion of the third step;
a fifth step of carrying out a flattening process on the main surface side until a surface of the second material film is exposed on the main surface side after completion of the fourth step;
a sixth step of carrying out a wet etching process using the second etchant so that the second material film on the main surface side is etched and removed until the first material film formed on the main surface side is exposed after completion of the fifth step; and
a seventh step of carrying out a wet etching process using the first etchant so that the first material film on the main surface side is etched and removed until the semiconductor substrate surface is exposed on the main surface side after completion of the sixth step, wherein
the first step includes forming the third material film having a thickness that is greater than a thickness by which the third material film is etched in the sixth and seventh steps.
